(19) United States
(12) Patent Application Publication
(10) Pub. No.: US 2008/0173792 A1
(43) Pub. Date: Jul. 24, 2008

(54) Image sensor module and the method of the same

(75) Inventors: Wen-Kun Yang, Hsin-Chu City (TW); Jui-Hsien Chang, Jhudong Township (TW); Tung-chuan Wang, Yangmei Town (TW); Chihwei Lin, Gueiren Township (TW); Hsien-Wen Hsu, Lujhou City (TW)

Correspondence Address: BACON & THOMAS, PLLC, 625 SLATERS LANE, FOURTH FLOOR, ALEXANDRIA, VA, 22314, US

(73) Assignee: Advanced Chip Engineering Technology Inc., Hukou Township (TW)

(21) Appl. No.: 11/656,410

(22) Filed: Jan. 23, 2007

(51) Int. Cl. H01L 27/00

(52) U.S. Cl. 250/208.1

(57) ABSTRACT

The present invention provides an image sensor module structure comprising a substrate with a die receiving cavity formed within an upper surface of the substrate and conductive traces within the substrate and a die having a micro lens disposed within the die receiving cavity. A dielectric layer is formed on the die and the substrate, a re-distribution conductive layer (RDL) is formed on the dielectric layer, wherein the RDL is coupled to the die and the conductive traces and the dielectric layer has an opening to expose the micro lens. A lens holder is attached on the substrate and the lens holder has a lens attached an upper portion of the lens holder. A filter is attached between the lens and the micro lens. The structure further comprises a passive device on the upper surface of the substrate within the lens holder.

### FIELD OF THE INVENTION

This invention relates to a structure of image sensor, and more particularly to an image sensor module with die receiving cavity.

### DESCRIPTION OF THE PRIOR ART

Digital video cameras are under development to facilitate as home appliances. Due to the quick development of the semiconductor technology, the application of the image sensor is widely used for digital still camera or movie camera. Consumers' demand has been directed to light weight, multi-function and high resolution. To meet such demand, technical levels of manufacturing camera have been improved. CCD or CMOS chip is popular device for these camera to capture image and die-bonded by means of a conductive adhesive. Typically, an electrode pad of the CCD or CMOS is wire-bonded by means of a metal wire. The wire bonding limits the size of the sensor module. The device is formed by traditional resin packaging method.

A commonly used conventional image sensor device has an array of photodiodes formed on the surface of the wafer substrate. The methods of forming such photo arrays are well known to those having ordinary skill in the art. Typically, the wafer substrate is mounted to a flat support structure and electrically connected to a plurality of electrical contacts. The substrate is electrically connected to bond pads of the support structure using wires. The structure is then enclosed in a package with a light transmissive surface that allows light to impinge on the array of photodiodes. In order to produce a flat image with relatively little distortion or little chromatic aberration requires the implementation of multiple lenses which are arranged to generate a flat optical plane. This can require many expensive optical elements.

Further, in the field of semiconductor devices, the device density is increased and the device dimension is reduced, continuously. The demand for the packaging or interconnecting techniques in such high density devices is also increased to fit the situation mentioned above. Conventionally, in the flip-chip attachment method, an array of solder bumps is formed on the surface of the die. The formation of the solder bumps may be carried out by using a solder composite material through a solder mask for producing a desired pattern of solder bumps. The function of chip package includes power distribution, signal distribution, heat dissipation, protection and support . . . and so on. As a semiconductor become more complicated, the traditional package technique, for example lead frame package, flex package, rigid package technique, can't meet the demand of producing smaller chip with high density elements on the chip. Because conventional package technologies have to divide a dice on a wafer into respective dies and then package the die respectively, therefore, these techniques are time consuming for manufacturing process. Since the chip package technique is highly influenced by the development of integrated circuits, therefore, as the size of electronics has become demanding, so does the package technique. For the reasons mentioned above, the trend of package technique is toward ball grid array (BGA), flip chip (FC-BGA), chip scale package (CSP), Wafer level package (WLP) today. “Wafer level package” is to be understood as meaning that the entire packaging and all the interconnections on the wafer as well as other processing steps are carried out before the singulation (dicing) into chips (dies). Generally, after completion of all assembling processes or packaging processes, individual semiconductor packages are separated from a wafer having a plurality of semiconductor dies. The wafer level package has extremely small-dimensions combined with extremely good electrical properties.

WLP technique is an advanced packaging technology, by which the die are manufactured and tested on the wafer, and then singulated by dicing for assembly in a surface-mount line. Because the wafer level package technique utilizes the whole wafer as one object, not utilizing a single chip or die, therefore, before performing a scribing process, packaging and testing has been accomplished; furthermore, WLP is such an advanced technique so that the process of wire bonding, die mount and under-fill can be omitted. By utilizing WLP technique, the cost and manufacturing time can be reduced, and the resulting structure of WLP can be equal to the die; therefore, this technique can meet the demands of miniaturization of electronic devices.

Therefore, the present invention provides an image sensor module to reduce the package size and cost.

### SUMMARY OF THE INVENTION

The object of the present invention is to provide an image sensor module to link to MB without “connector” for BGA/LGA type.

The object of the present invention is to provide an image sensor module with PCB having cavities for super thin module application and small foot print (form factor), simple process for CIS module.

The further object of the present invention is to provide an image sensor module which is re-workable by de-soldering.

The present invention provides an image sensor module structure comprising: a substrate with a die receiving cavity formed within an upper surface of the substrate and conductive traces within the substrate; a die having a micro lens disposed within the die receiving cavity; a dielectric layer formed on the die and the substrate; a re-distribution conductive layer (RDL) formed on the dielectric layer, wherein the RDL is coupled to the die and the conductive traces, wherein the dielectric layer has an opening to expose the micro lens; a lens holder attached on the substrate, the lens holder having a lens attached an upper portion of the lens holder, a filter attached between the lens and the micro lens. The structure further comprises a passive device on the upper surface of the substrate within the lens holder.

It should be noted that an opening is formed within the dielectric layer and a top protection layer to expose the micro lens area of the die for CMOS Image Sensor (CIS). A transparent cover with coating IR filter is optionally formed over the micron lens area for protection.

The image sensor chips has been coated the protection layer (film) on the micro lens area; the protection layer (film) with the properties of water repellent and oil repellent that can away the particle contamination on the micro lens area; the thickness of protection layer (film) preferably around 0.1 um to 0.3 um and the reflection index close to air reflection index 1. The process can be executed by SOG (spin on glass) skill and it can be processed either in silicon wafer form or panel wafer form (preferably in silicon wafer form to avoid the particle contamination during further process). The materials of protection layer can be SiO₂, Al₂O₃ or Fluoro-polymer etc.

The dielectric layer includes an elastic dielectric layer, silicone dielectric based material, BCB or PI. The silicone dielectric based material comprises siloxane polymers (SINR), silicon oxide, silicon nitride, or composites thereof. Alternatively, the dielectric layer comprises a photosensitive layer. The RDL communicates to the terminal pads downwardly the contacting via through holes structure.

The material of the substrate includes organic epoxy type FR4, FR5, BT, PCB (print circuit board), alloy or metal. The alloy includes Alloy42 (42% Ni-58% Fe) or Kovar (29% Ni-17% Co-54% Fe). Alternatively, the substrate could be glass, ceramic or silicon.

### BRIEF DESCRIPTION OF THE DRAWINGS

FIG. 1 illustrates a cross-sectional view of a structure of image sensor module according to the present invention.

FIG. 2 illustrates a cross-sectional view of a cavity area structure according to the present invention.

FIG. 3 illustrates a cross-sectional view of a structure of image sensor module according to the present invention.

FIG. 4 illustrates a cross-sectional view of a structure of image sensor module according to the present invention.

FIG. 5 illustrates a cross-sectional view of a structure of image sensor module according to the present invention.

FIG. 6 illustrates a cross-sectional view of a structure of image sensor module according to the present invention.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

The present invention discloses a structure of an image sensor module utilizing a substrate having predetermined cavity formed into the substrate. A photosensitive material is coated over the die and the pre-formed substrate. Preferably, the material of the photosensitive material is formed of elastic material. The image sensor module comprising PCB mother board with cavity for Image Sensor chip and build up layers are employed. The module with super thin structure is less than 400 um. The image sensor chips can be processed by WLP to form the protection layer on micro lens and using the build up layers to form the RDL on the module with passive components. The protection layer on micro lens may prevent the chip from particle contamination and it has water/oil repellent and the thickness of the layer is less than 0.5 um. The lens holder with IR cart can be fixed on the PCB mother board (on top the micro lens area). The high yield and high quality process can be achieved by the present invention.

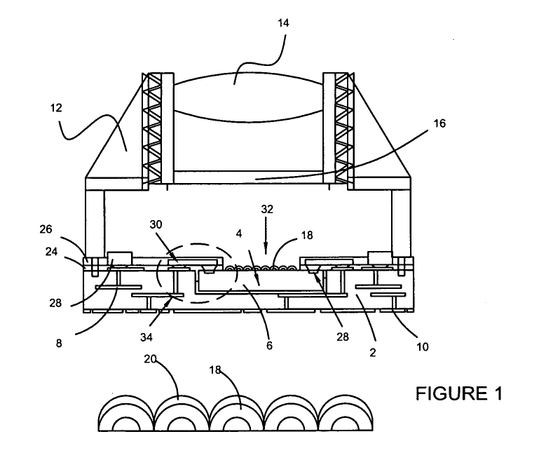

FIG. 1 illustrates a cross-sectional view of the image sensor module in accordance with one embodiment of the present invention. As shown in the FIG. 1, the structure includes a substrate 2 having a die receiving cavity 4 formed therein to receive a die 6. Pluralities of conductive traces 8 are created in the substrate 2 for electrical communication. Terminal Pads 10 are located on the lower surface of the substrate 2 and connected to the traces 8. A lens holder 12 is formed over the substrate for carrying the lens and protection. Lens 14 is attached on the upper portion of the lens holder 12. A filter 16 is located within the lens holder 12 and between the lens 14 and the micro lens 18 of the substrate 2, the filter 16 can be omitted once it combine with lens 14 together. The micro lens 18 includes a protection layer 20 formed thereon.

The die 6 is disposed within the die receiving cavity 4 on the substrate 2 and fixed by an adhesion (die attached) material 22. As know, contact pads (Bonding pads) 28 are formed on the die 6. A photosensitive layer or dielectric layer 24 is formed over the die 6 and filling into the gap between the die 6 and the side walls of the cavity 4. Pluralities of openings are formed within the dielectric layer 24 through the lithography process or exposure and development procedure. The pluralities of openings are aligned to the contact or I/O pads 28, respectively. The RDL (re-distribution layer) 30, also referred to as metal trace, is formed on the dielectric layer 24 by removing selected portions of metal layer formed over the layer, wherein the RDL 30 keeps electrically connected with the die 6 through the I/O pads 28. A part of the material of the RDL will re-fills into the openings in the dielectric layer 24, thereby forming contact via metal over the bonding pad 28. A protection layer 26 is formed to cover the RDL 30. The aforementioned structure constructs LGA type image sensor module.

It should be noted that an opening 32 is formed within the dielectric layer 26 and the layer 24 to expose the micro lens 18 of the die 6 for CMOS Image Sensor (CIS). A protection layer 20 can be formed over the micro lens 18 on the micro lens area. The opening 32 is typically formed by photolithography process as well known to the skilled person in the art. In one case, the lower portion of the opening 32 can be opened during the formation of via opening. The upper portion of the opening 32 is formed after the deposition of the protection layer 26. Alternatively, the whole opening 32 is formed after the formation of the protection layer 26 by lithography. The image sensor chips has been coated the protection layer (film) 20 on the micro lens area; the protection layer (film) with the properties of water repellent and oil repellent that can away the particle contamination on the micro lens area. The thickness of protection layer (film) 20 is preferably around 0.1 um to 0.3 um and the reflection index close to the air reflection index 1. The process can be executed by SOG (spin on glass) skill and it can be processed either in silicon wafer form or panel wafer form (preferably in silicon wafer form to avoid the particle contamination during further process). The materials of protection layer can be SiO₂, Al₂O₃ or Fluoro-polymer etc. Finally, a transparent cover 16 with coating IR filter is optionally formed over the micron lens 18 for protection. The transparent cover 16 is composed of glass, quartz, etc. It should be noted that the passive device 28 may be formed on the substrate and within the lens holder 12.

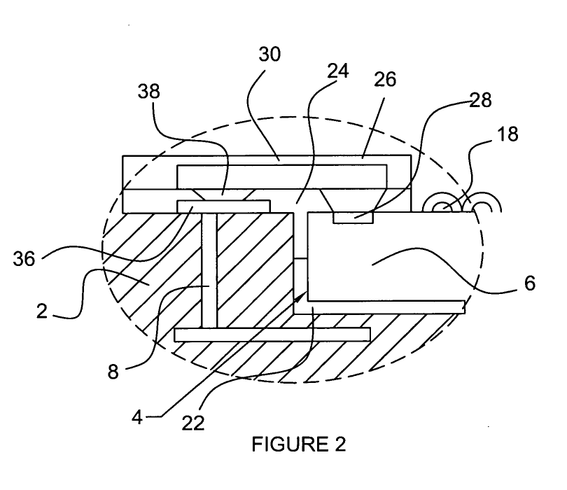

FIG. 2 shows the cross sectional view of the cavity area 34. From the illustration, contact metal pad 36 is formed on the substrate 2. A contact via 38 is aligned to the contact metal pad 36. The die 6 may communicate to the traces 8 within the PCB via the RDL 30 and the pad 28. The material of the layer 24 refills into the gap between the die 6 and the cavity sidewall.

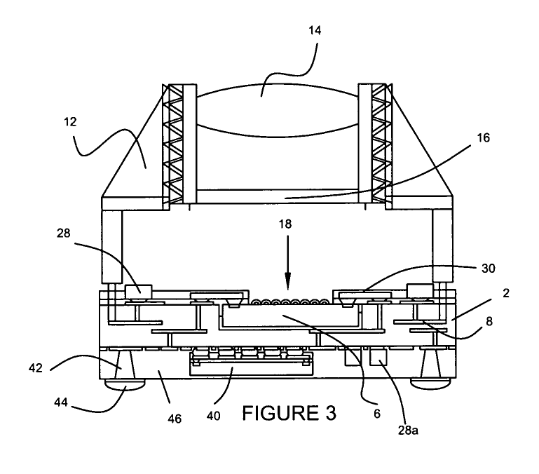

An alternative embodiment can be seen in FIG. 3, most of the structures are similar to FIG. 1, therefore, the detailed description is omitted. A second die 40 is attached on the lower surface of the substrate 2 and outside the lens holder 12. In one case, the second die 40 is attached by flip chip bumps and RDL. The second die is DSP or MCU for auto focus. A dielectric layer 46 is formed on the lower surface of the substrate. Through-hole structures 42 are formed within the layer 46 and terminal contact pads 44 are coupled to through-hole structures 42. Second passive devices 28a may be formed on the lower surface of the substrate 2 and covered by the dielectric layer 46.

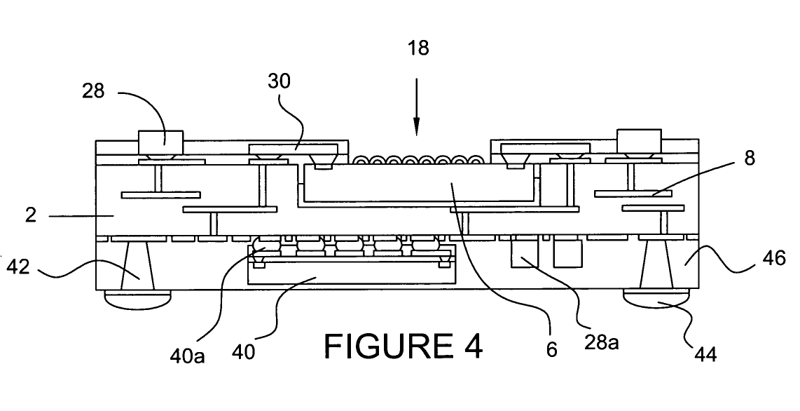

Please refer to FIG. 4, it shows the detailed of the substrate 2 of FIG. 3 and the components formed thereon. The second die 40 includes solder joint 40a for coupling to the traces 8 on the lower surface of the substrate 2. The first and second passive devices may be formed by SMT (surface mounting technology).

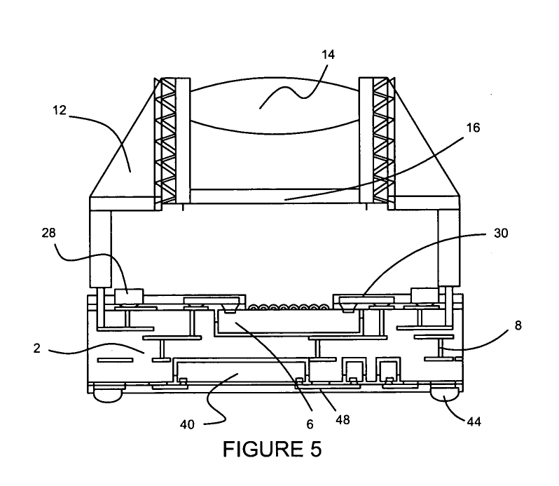

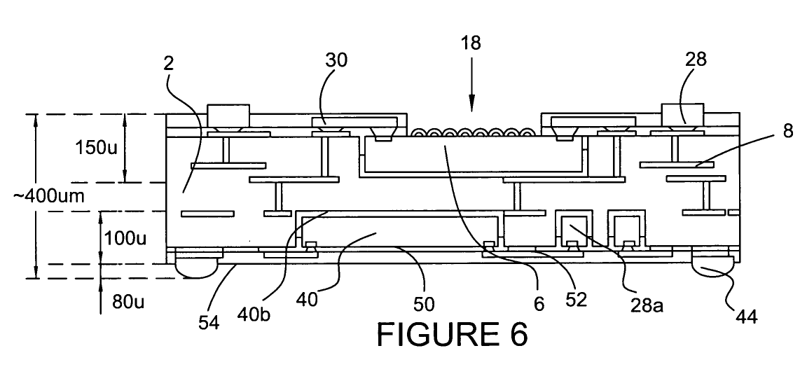

Alternatively, further die receiving cavity 4a is formed on the lower surface of the substrate 2 to receive the second die 40 which is DSP or MCU for auto focus, as shown in FIG. 5. A second RDL 48 is constructed on the second die 40 for electrical communication. The second passive devices 28a may be formed within the substrate 2 for better topography. The terminal contacts 44 are coupled to the traces 8. FIG. 6 shows the detailed of the substrate 2 of FIG. 5 and the components formed thereon. The second die 40 is attached within the cavity 4a via the attaching material 40b. A dielectric layer 50 is formed on the second die 40 and a second RDL 52 is formed over the dielectric layer 50. A protection layer 54 is formed on the second RDL 52 for protection. The second passive devices 28a may be embedded within the substrate 2. The bump type terminal contacts 44 couple to the traces 8. This type is called BGA (Ball Grid Array) type.

Preferably, the material of the substrate 2 is organic substrate likes FR5, BT (Bismaleimide triazine), PCB with defined cavity or Alloy42 with pre etching circuit. The organic substrate with high Glass transition temperature (Tg) are epoxy type FR5 or BT (Bismaleimide triazine) type substrate. The Alloy42 is composed of 42% Ni and 58% Fe. Kovar can be used also, and it is composed of 29% Ni, 17% Co, 54% Fe. The glass, ceramic, silicon can be used as the substrate due to lower CTE. The dimension of the depth of the cavity 4, 4a could be larger than the thickness of the die 6, 40. It could be deeper as well.

The substrate could be round type such as wafer type, the diameter could be 200, 300 mm or higher. It could be employed for rectangular type such as panel form. The substrate 2 is formed with cavities 4 and built in circuit 8.

In one embodiment of the present invention, the dielectric layer 24 is preferably an elastic dielectric material which is made by silicone dielectric materials comprising siloxane polymers (SINR), silicon oxide, silicon nitride, and composites thereof. In another embodiment, the dielectric layer is made by a material comprising benzocyclobutene (BCB), epoxy, polyimides (PI) or resin. Preferably, it is a photosensitive layer for simple process. In one embodiment of the present invention, the elastic dielectric layer is a kind of material with CTE larger than 100 (ppm/° C.), elongation rate about 40 percent (preferably 30 percent-50 percent), and the hardness of the material is between plastic and rubber. The thickness of the elastic dielectric layer 24 depends on the stress accumulated in the RDL/dielectric layer interface during temperature cycling test.

In one embodiment of the invention, the material of the RDL comprises Ti/Cu/Au alloy or Ti/Cu/Ni/Au alloy; the thickness of the RDL is between 2 um_and_{—}15 um. The Ti/Cu alloy is formed by sputtering technique also as seed metal layers, and the Cu/Au or CU/Ni/Au alloy is formed by electroplating; exploiting the electro-plating process to form the RDL can make the RDL thick enough to withstand CTE mismatching during temperature cycling. The metal pads 28 can be Al or Cu or combination thereof. In case of the structure of FO-WLP utilizes SINR as the elastic dielectric layer and Cu as the RDL metal. According to the stress analysis not shown here, the stress accumulated in the RDL/dielectric layer interface is reduced.

As shown in FIG. 1-6, the RDL metal fans out of the die 6 and the communicates downwardly toward the terminal pads 10 or 44 under the structure. It is different from the prior art technology which stacks layers over the die, thereby increasing the thickness of the package. However, it violates the rule to reduce the die package thickness. On the contrary, the terminal pads are located on the surface that is opposite to the die pads side. The communication traces 8 are penetrates through the substrate 2. Therefore, the thickness of the die package is apparently shrinkage. The package of the present invention will be thinner than the prior art. Further, the substrate is pre-prepared before package. The cavity 4 and the traces 8 are pre-determined as well. Thus, the throughput will be improved than ever. The present invention discloses a fan-out WLP without stacked built-up layers over the RDL.

The present invention provides the PCB (FR5/BT) with CIS die cavity. Then, the next step is to pick the CIS die (from blue tape flame) and attach the die into the cavity. Then, the attached material is cured and the die surface and metal pads is cleaned. Build up layers (RDL) process is performed to form the RDL. Then, pick and place the passive components on the PCB by picking and placing tool. Subsequently, IR reflow is used to solder PCB and passive components, followed by flux cleaning the PCB. Next is to mount the lens holder and fix the holder on the PCB, followed by module testing.

Another method further includes picking up the flip chip die (DSP or MCU) and passive components, followed by attaching the devices on the lower surface of the substrate before IR reflow is performed.

For multi-chip application, the steps include: providing the PCB (FR5/BT) with CIS die and MCU/DSP die cavities; picking the MCU die/RC and attaching on the bottom side of FR5/BT; curing and cleaning the surface and forming the build up layers; picking the CIS die and attaching on the upper side of FR5/BT; curing and cleaning the die surface and metal pads; forming Build up layers (RDL); picking and placing the passive components on the PCB; IR reflowing to solder PCB and passive components; flux cleaning the PCB; mounting the lens holder and fix the holder on the PCB; module testing.

The advantages of the present invention are:
Module linking with MB (mother board) without “connector” for BGA/LGA type
Build up layers process is sued for CIS module onto MB
PCB with cavities for super thin module
Small foot print (form factor)
Simple process for CIS module
Solder join terminal pins are standard format (for LGA/BGA type)
Module re-workable by de-soldering from MB
Highest yield during manufacturing in module/system assembly
Protection layer is on the micro lens to prevent particle contamination
Lowest cost substrate (PCB-FR4 or FR5/BT type)
High yield due to build up layers process

Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. An image sensor module structure comprising:
a substrate with a first die receiving cavity formed within an upper surface of said substrate and conductive traces within said substrate;
a first die having a micro lens disposed within said first die receiving cavity;
a first dielectric layer formed on said first die and said substrate;
a first re-distribution conductive layer (RDL) formed on said first dielectric layer, wherein said first RDL is coupled to said first die and said conductive traces, wherein said first dielectric layer has an opening to expose said micro lens;
a lens holder attached on said substrate, said lens holder having a lens attached an upper portion of said lens holder.

2. The structure of claim 1, further comprising a first passive device on said upper surface of said substrate within said lens holder.

3. The structure of claim 1, further comprising an IR filter attached between said lens and said micro lens.

4. The structure of claim 1, wherein said first dielectric layer includes an elastic dielectric layer

5. The structure of claim 1, wherein said first dielectric layer comprises a silicone dielectric based material, BCB or PI.

6. The structure of claim 5, wherein said silicone dielectric based material comprises siloxane polymers (SINR), silicon oxide, silicon nitride, or composites thereof.

7. The structure of claim 1, wherein said first dielectric layer comprises a photosensitive layer.

8. The structure of claim 1, wherein said first RDL is made from an alloy comprising Ti/Cu/Au alloy or Ti/Cu/Ni/Au alloy.

9. The structure of claim 1, wherein the material of said substrate includes epoxy type FR5, FR4, BT, PCB (print circuit board), glass, ceramic, silicon, alloy or metal.

10. The structure of claim 9, wherein the material of said substrate includes Alloy42 (42% Ni-58% Fe) or Kovar (29% Ni-17% Co-54% Fe).

11. The structure of claim 1, further comprising a second die attached on a lower surface of said substrate.

12. The structure of claim 11, wherein said second die is attached on a second die receiving cavity formed with said lower surface of said substrate.

13. The structure of claim 12, further comprising a second RDL formed on said second die.

14. The structure of claim 11, further comprising a protection dielectric layer formed on said lower surface to cover said substrate.

15. The structure of claim 11, further comprising a second passive device on said lower surface of said substrate.

16. The structure of claim 11, further comprising a terminal contacts formed at said lower surface of said substrate.

17. The structure of claim 1, further comprising a protection layer formed on said the micro lens to prevent particle contamination.

18. The structure of claim 17, the materials of said protection layer including SiO₂, Al₂O₃ or Fluoro-polymer.

19. The structure of claim 17, wherein said protection layer with water repellent and oil repellent properties

20. A method for forming semiconductor device package comprising:
providing a substrate with a die receiving cavity formed within an upper surface of said substrate and a conductive trace formed therein;
picking and attaching a die into said cavity;
cleaning die surface and pads;
forming a RDL on said die;
picking and placing passive components on said substrate by picking and placing tool;
soldering said passive components on said substrate by an IR reflow; and
mounting a lens holder on said substrate.

21. The method of claim 20, further including picking a flip chip die, followed by attaching said flip chip die on a lower surface of said substrate before said IR reflow is performed.

22. A method for forming semiconductor device package comprising:
providing a substrate with a first and second die receiving cavity formed within an upper and a lower surfaces of said substrate and a conductive trace formed therein;
picking and attaching a first die and a second die into said first and second die receiving cavity, respectively;
forming build up layers on said first and second die respectively; and
mounting a lens holder on said substrate.

23. The method of claim 21, further including picking and placing passive components on said substrate before said IR reflow is performed.
